(19) United States
(12) Patent Application Publication
(10) Pub. No.: US 2025/0383834 A1
(43) Pub. Date: Dec. 18, 2025

(54) AUDIO PROCESSING

(71) Applicant: Cirrus Logic International Semiconductor Ltd., Edinburgh (GB)

(72) Inventors: Andrew I. BOTHWELL, Edinburgh (GB); Jonathan E. EKLUND, Austin, TX (US); David PEYER, Austin, TX (US); Shahram TADAYON, Austin, TX (US); Royston SIOW, Austin, TX (US)

(73) Assignee: Cirrus Logic International Semiconductor Ltd., Edinburgh (GB)

(21) Appl. No.: 19/058,107

(22) Filed: Feb. 20, 2025

Related U.S. Application Data
(60) Provisional application No. 63/659,943, filed on Jun. 14, 2024.
(60) Provisional application No. 63/662,001, filed on Jun. 20, 2024.

(51) Int. Cl. G06F 3/16; H03F 3/183

(52) U.S. Cl. CPC G06F 3/165; G06F 3/162; H03F 3/183; H03F 2200/03

(57) ABSTRACT

A system, comprising: main circuitry, comprising: a central processor; memory comprising software instructions which when executed by the central processor cause the central processor to: selectively apply one or more software audio effects to an audio signal to generate a first software processed audio signal; and output the first software processed audio signal; audio processing circuitry, comprising: an audio processor configured to: receive the first software processed audio signal; apply first hardware audio effects to the first software audio signal to generate a first hardware processed audio signal; and output an output audio signal derived from the first hardware processed audio signal; and a controller configured to dynamically adjust the first hardware audio effects applied to the first software processed audio signal in dependence on a characteristic of the first software processed audio signal.

### TECHNICAL FIELD

The present disclosure relates to systems and methods of audio processing.

### BACKGROUND

Audio processing in personal computers (PCs) is typically implemented primarily in software. For example, in operating systems such as the Windows Operating System from Microsoft Corporation, audio processing is implemented using audio processing objects (APOs). An APO is an object that contains an algorithm which provides a specific digital signal processing (DSP) effect (an “audio effect”). APOs typically runs on a central processing unit (CPU) of a PC or a DSP integrated into a system on chip (SoC) of the PC. APOs may compensate for speaker and/or acoustic design characteristics or provide for improved and/or optimized audio output from the PC.

Performing software processing of audio streams within an operating system can lead to high power consumption. As such, is it known to offload some audio processing to an on-chip digital signal processor (DSP) local to the CPU running the APO. However, in such configurations, the DSP may not be able to support all audio processing modes required. As such, an APO is typically still required to achieve a level of audio quality intended by PC manufacturers.

In practice, the reliance on dedicated APOs to achieve quality audio effects for PCs leads to several problems. APO software can be of considerable size, typically in the order of hundreds of megabytes. PC users or information technology (IT) departments can view APOs as undesirable or unnecessary (so-called “bloatware”) and delete this software from the PCs or not include them in a corporate software image. As a result, PC original equipment manufacturers (OEMs) cannot be confident PCs operating in the manner they intended, potentially leading to negative customer experience.

### SUMMARY

Embodiments of the present disclosure aim to address or at least ameliorate one or more of the above issues by providing a system architecture for a PC which offloads baseline audio processing to an audio processor (e.g. DSP) provided on a peripheral device, such as an amplifier or CODEC configured to drive an output audio transducer of the PC, or an external low power DSP core. To ensure cooperation between software and peripheral hardware audio processing, a controller may be provided to coordinate and/or allocate specific audio effects to software and hardware modules. In doing so, quality of audio output from the PC can be ensured regardless of the presence or absence of a software

According to an aspect of the disclosure, there is provided a system, comprising: main circuitry, comprising: a central processor; memory comprising software instructions which when executed by the central processor cause the central processor to: selectively apply one or more software audio effects to an audio signal to generate a first software processed audio signal; and output the first software processed audio signal; audio processing circuitry, comprising: an audio processor configured to: receive the first software processed audio signal; apply first hardware audio effects to the first software audio signal to generate a first hardware processed audio signal; and output an output audio signal derived from the first hardware processed audio signal; and a controller configured to dynamically adjust the first hardware audio effects applied to the first software processed audio signal in dependence on a characteristic of the first software processed audio signal.

The controller may be implemented at least partially in software by the main circuitry Additionally or alternatively, the controller may be at least partially implemented in hardware. For example, the controller may be integrated into the audio processing sub-system.

The controller may be configured to dynamically adjust the first hardware effects based on one or more of: a. header information in a data stream comprising the first software processed audio signal; and b. one or more data flags embedded into the data stream; c. one or more data flags obtained from the main circuitry.

The controller may be configured to dynamically adjust the first hardware effects based on analysis of the first software processed audio signal.

Analysis of the first software processed audio signal may comprise determining a level of processing performed on the audio signal to obtain the first software processed audio signal.

The controller may be configured to dynamically adjust the first hardware audio effects based on a command from the central processor or based on a configuration set by the central processor.

The first hardware audio effects may comprise one or more of: baseline speaker protection; rattle distortion reduction; distortion limiting; crossover filtering; spatial processing. equalization; virtual and/or dynamic bass enhancement.

The controller may be configured to control the audio processor to continuously apply baseline hardware audio effects to the first software processed audio signal to maintain a quality metric of the first hardware processed audio signal above a predetermined quality threshold.

The baseline set of hardware audio effects may comprise one or more of: baseline speaker protection; rattle distortion reduction; distortion limiting; crossover filtering.

The first hardware audio effects may comprise one or more of: spatial processing; equalization; virtual and/or dynamic bass enhancement.

The main circuitry may be configured to output the audio signal. The audio processor may be configured to: receive the audio signal via a separate input path to the first software processed audio signal; and apply second hardware audio effects to the audio signal to obtain a second hardware processed audio signal.

The controller may be configured to dynamically adjust the second hardware audio effects applied to the audio signal.

The audio processor may be configured to mix the first and second hardware processed audio signals to obtain the output audio signal.

The system may further comprise a communications channel between the main circuitry and the audio processing circuitry.

The audio processor and/or the controller may be configured to write configuration data to the memory of the main circuitry. The configuration data may indicate the first hardware audio effects applied to the first software processed audio signal.

The system may further comprise an audio transducer configured to receive the output audio signal.

The audio processing circuitry may comprise an amplifier configured to amplify the first hardware processed audio signal to obtain the output audio signal.

The first hardware processed audio signal may be a digital signal. The audio processing circuitry may comprise a digital-to-analog converter (DAC) for converting the first hardware processed audio signal to the analog domain.

The audio processing circuitry may comprise an audio CODEC configured to generate the output audio signal.

The main circuitry may be integrated into a first integrated circuit (IC). The audio processing circuitry may be integrated into a second IC separate from the first IC.

The controller may be integrated into the second IC.

The controller may be integrated into a third IC separate from the first and second ICs.

According to another aspect of the disclosure, there is provided a system, comprising: main circuitry, comprising: a central processor; memory comprising software instructions which when executed by the central processor cause the central processor to: selectively apply one or more software audio effects to an audio signal to generate a first software processed audio signal; and output the audio signal and the first software processed audio signal; audio processing circuitry, comprising: an audio processor configured to: receive the audio signal and the first software processed audio signal; apply first hardware audio effects to the audio signal to generate a first hardware processed audio signal; apply second hardware audio effects to the first software audio signal to generate a second hardware processed audio signal; mix the first and second hardware processed audio signals to generate a mixed hardware processed signal; and output an output audio signal derived from the mixed hardware processed audio signal.

The main circuitry may comprise a class driver and a streaming driver stored in the memory which, when executed by the central processor, cause the processor to output the audio signal and the first software processed audio signal to first and second data ports of the main circuitry.

According to another aspect of the disclosure, there is provided an electronic device, comprising the system described above.

According to another aspect of the disclosure, there is provided an audio processor integrated circuit, comprising: audio processing circuitry, comprising: an audio processor configured to: receive a first software processed audio signal; apply first hardware audio effects to the first software audio signal to generate a first hardware processed audio signal; and output an output audio signal derived from the first hardware processed audio signal; and a controller configured to dynamically adjust the first hardware audio effects applied to the first software processed audio signal in dependence on a characteristic of the first software processed audio signal.

According to another aspect of the disclosure, there is provided an audio processor integrated circuit, comprising audio processing circuitry configured to: receive an audio signal and a first software processed audio signal, one or more software audio effects having been applied to the audio signal to generate the first software processed audio signal; apply first hardware audio effects to the audio signal to generate a first hardware processed audio signal; apply second hardware audio effects to the first software audio signal to generate a second hardware processed audio signal; mix the first and second hardware processed audio signals to generate a mixed hardware processed signal; and output an output audio signal derived from the mixed hardware processed audio signal.

The electronic device may comprise one of a wearable device, an analyte monitoring device, an analyte sensing device, a battery, a battery monitoring device, a mobile computing device, a laptop computer, a tablet computer, a games console, a remote control device, a home automation controller or a domestic appliance, a toy, a robot, an audio player, a video player, or a mobile telephone, and a smartphone.

Throughout this specification the word “comprises”, or variations such as “comprises” or “comprising”, will be understood to imply the inclusion of a stated element, integer or step, or group of elements, integers or steps, but not the exclusion of any other element, integer or step, or group of elements, integers or steps.

### BRIEF DESCRIPTION OF DRAWINGS

Embodiments of the present disclosure will now be described by way of non- limiting examples with reference to the drawings, in which:

FIG. 1 is schematic diagram of a known personal computer (PC) system;

FIG. 2 is a flow diagram illustrating processing of an audio signal by the PC system of FIG. 1;

FIG. 3 is schematic diagram of a system according to the present disclosure;

FIG. 4 is a flow diagram illustrating processing of an audio signal by the system of FIG. 3;

FIG. 5 is a schematic diagram of a system which is a variation of the system of FIG. 3; and

FIG. 6 is a schematic diagram of a system which is a variation of the system of FIG. 3.

### DESCRIPTION OF EMBODIMENTS

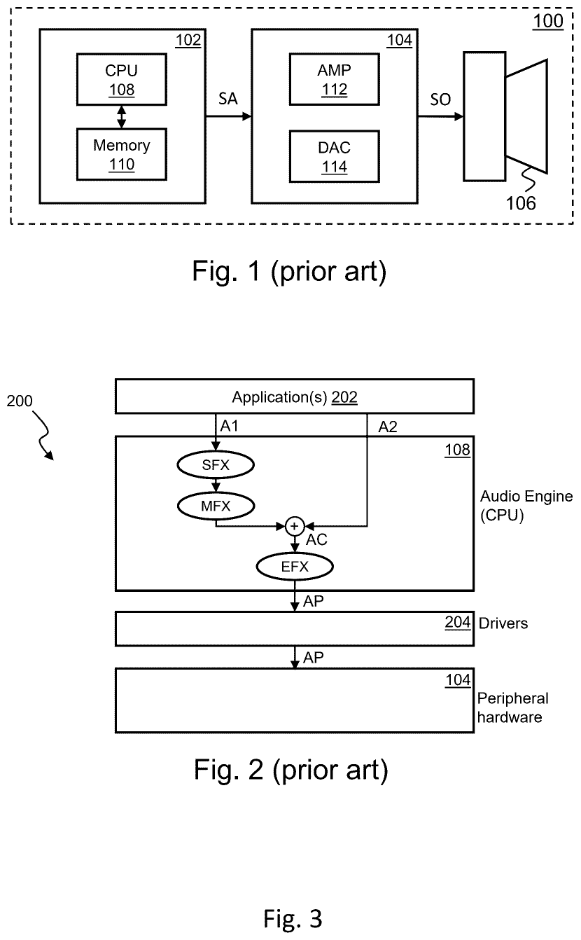

FIG. 1 is a schematic diagram of a known personal computer (PC) 100. For clarity of explanation, various elements of the PC 100 are not shown in FIG. 1.

The PC 100 comprises main circuitry 102, peripheral audio processing circuitry 104, and an output audio transducer 106.

The main circuitry 102 comprises a central processing unit (CPU) 108 and memory 110. The memory 110 may store instructions which, when executed by the CPU 108 may cause the processor to generate an audio signal. Alternatively, the audio signal may be generated elsewhere in the main circuitry 102 or external to main circuitry 102. The CPU 108 may be configured to run one or more audio processing objects (APOs) which may also be stored in the memory 110. Thus, the CPU 108 may be configured to process the audio signal to generate a processed audio signal SA which may be stored in the memory 110 and/or transmitted to the peripheral audio processing circuitry 104. Optionally, the main circuitry 102 may comprise a digital signal processor (DSP) (not shown) which may be integrated on to the same system on chip (SoC) as the CPU 108.

The peripheral audio processing circuitry 104 may comprise an amplifier 112 and a digital-to-analog converter (DAC) 114. The DAC 114 may be configured to convert processed audio signal SA to an analog audio signal SO to be output to the transducer 106. The amplifier 112 may be configured to amplify the processed audio signal SA for output as the output signal SO. Amplification may be performed in the digital domain (before conversion by the DAC 114) or in the analog domain (after conversion by the DAC 114). The output signal SO is then output to the transducer 106 to be played back to the user.

FIG. 2 is a flow diagram illustrating an example audio processing flow 200 for the PC 100 shown in FIG. 1.

One or more applications 202 running on the main circuitry 102 may each generate an audio stream A1, A2. In the example shown, two audio streams A1, A2 are generated. An APO running on the CPU 108 may apply one or more audio effects to one or both of the audio streams A1, A2. In the example shown, audio stream effects (SFX) and effects are applied to the first audio stream A1, and no effects are applied to the second audio stream A2. The audio streams A1, A2 may be combined to obtain a combined audio stream AC and one or more audio endpoint effects (EFX) may be applied to the combined audio stream AC. The processed audio stream AP may then be output using one or more software drivers 204 to the peripheral audio processing circuitry 104 for conversion and amplification.

In the conventional arrangement shown in FIG. 1 and described with reference to FIG. 2, all audio effects are implemented in software by an APO running on the main circuitry 102, whilst the peripheral audio processing circuitry performs only digital-analog conversion and amplification. There are several drawbacks to this arrangement. Firstly, an APO is typically computationally intensive resulting in energy consumption. This is of particular disadvantage for battery powered devices, such as laptop computers. Secondly, APOs tend to be large in size, for example in the order of hundreds of megabytes. In view of this, PC users and corporate IT departments often delete APOs or omit them from PC builds to reduce memory usage, as they deem such software objects unnecessary “bloatware”. Since such actions are outside of the control of OEMs, the quality of signals output from the main circuitry 102 to the peripheral audio processing circuitry 104 cannot be guaranteed. This can lead to undesirable results for the PC user with respect to their overall audio experience.

Embodiments of the present disclosure aim to address this issue in two aspects. The first aspect is to provide peripheral audio processing functionality separate from the main circuitry 102. Doing so had several advantageous effects. For example, power consumption can be reduced when compared to purely software implemented audio processing. Additionally, control of audio processing (or lack thereof) can be maintained with the OEM as opposed to the user of IT department, since hardware cannot be removed or bypassed. As such, quality of audio being output from a system can be more stringently controlled. Embodiments of the present disclosure also implement novel control architecture to enable successful offload of audio processing to peripheral hardware. In particular, a controller is proposed which is configured to dynamically adjust audio effects applied in hardware in dependence on audio signal(s) generated and/or output from main circuitry in a computer system or on the basis of the software effects already applied to those audio signal(s).

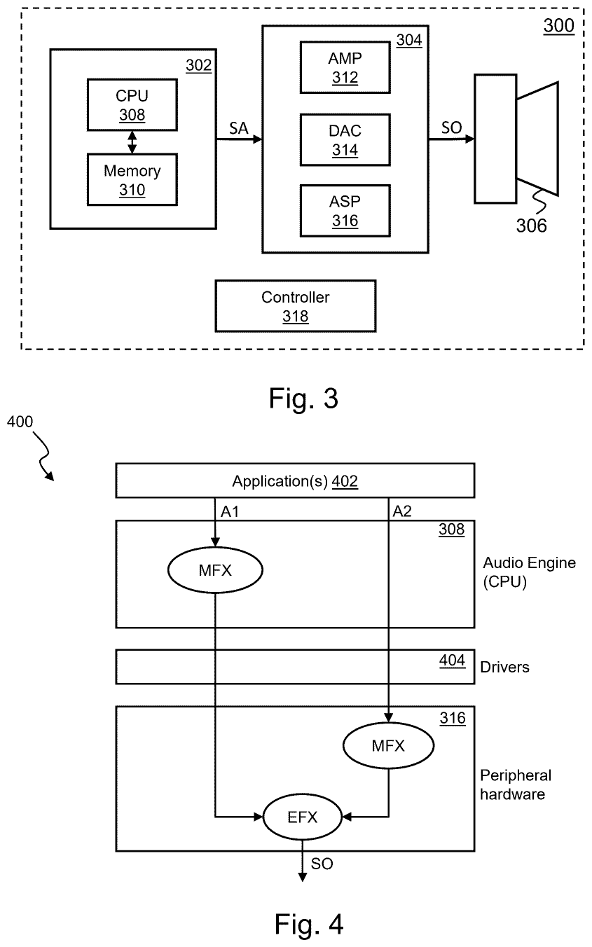

FIG. 3 is a schematic diagram of system 300 according to embodiments of the present disclosure. The system 300 may, for example, be a PC. For clarity of explanation, various elements of the system 300 are not shown in FIG. 3.

The system 300 comprises main circuitry 302, peripheral audio processing circuitry 304, and an output audio transducer 306.

The main circuitry 302 is similar to the main circuitry 102 of the PC 100 of FIG. 1 and comprises a CPU 308 and a memory 310. The memory 310 may store instructions which, when executed by the CPU 308 may cause the processor to generate an audio signal. Alternatively, the audio signal may be generated elsewhere in or external to the main circuitry 302. The CPU 308 may be configured to run one or more audio processing objects (APOs) which may also be stored in the memory 110. Thus, the CPU 308 may be configured to process the audio signal to generate a processed audio signal SA which may be stored in the memory 310 and/or transmitted to the peripheral audio processing circuitry 304. Alternatively, audio processing may be performed in software without an APO.

In some embodiments, the CPU 308 implementing an APO may be configured to output multiple audio data streams to the peripheral audio processing circuitry 304. For example, the CPU 308 may be configured to output the raw audio signal (absent of any audio effects) in addition to the software processed audio signal SA. In another, the CPU 308 may be configured to apply a first set of audio effects to the audio signal to be output as the software processed audio signal, and a second set of audio effects to the audio signal to be output as an additional (second) processed audio signal. In another example, audio signals from separate applications may be kept separate (i.e. not mixed by the main circuitry 302) and output separately to the peripheral audio processing circuitry 304. Optionally, audio effects may be applied to one or some of the separate audio signals from each application. In the following passages, whilst a single audio signal SA is described as being provided to the peripheral audio processing circuitry 304, the explanation of processing will be similar to additional audio signals, if provided.

In some embodiments, for example where a user or IT department have removed an APO from the main circuitry 302, the APO may not be present. In which case, limited or no audio processing may take place on the main circuitry 102.

The transducer 306 may be coupled to the peripheral audio processing circuitry 304 via a wired or wireless link. For example, where the system 300 is a PC, the transducer 306 may be integrated into the PC. Alternatively, the transducer 306 may be a wireless speaker or headphones separate from system 300. Whilst a single transducer 306 is shown, multiple transducers may be coupled to the system 300 (wired or wirelessly).

The peripheral audio processing circuitry 304 may comprise an amplifier 312 and/or a digital-to-analog converter (DAC) 314. For example, in some embodiments, the peripheral audio processing circuitry 304 may comprise only the amplifier 312, or only the DAC 314. In which case, functionality of those components may be implemented external to the peripheral audio processing circuitry 304. If present, the DAC 314 may be configured to convert the processed audio signal SA to an analog audio signal SO to be output to the transducer 306. If present, the amplifier 312 may be configured to amplify the processed audio signal SA for output as the output signal SO. Amplification may be performed in the digital domain (before conversion by the DAC 314) or in the analog domain (after conversion by the DAC 314). The peripheral audio processing circuitry 304 may implement a CODEC for driving the audio transducer 306 and/or for driving an audio peripheral (e.g. and audio headset of satellite speaker) via a wired or wireless connection. As such, the peripheral audio processing circuitry 304 may comprise an ADC and/or transceiver circuitry to achieve such functionality.

In contrast to the PC 100 shown in FIG. 1, the peripheral audio processing circuitry 304 additionally comprises an audio signal processor 316 and a controller 318. The audio signal processor (ASP) 316 is configured to apply one or more audio effects to the audio signal SA received from the main circuitry 302, as will be described in more detail below. Such audio effects may comprise SFX, MFX and/or EFX. The received audio signal SA may be received from a transducer or line in, or alternatively may be generated onboard the main circuitry 302. The ASP 316 may comprise a digital signal processor (DSP). Additionally, or alternatively, the ASP 316 may comprise a combination of logic gates configurable to apply one or more audio effects to the audio signal SA. The ASP 316 may be configured to apply such audio effects in the digital domain, the analog domain, or both in the digital and analog domain. For example, when implemented in digital logic, the ASP 316 may be configured to apply audio effects to the audio signal SA before conversion and/or amplification by the DAC 314 and/or amplifier 312.

Examples of audio effects which may be applied by the ASP 316 include but are not limited to baseline speaker protection, rattle distortion reduction, distortion limiting, crossover filtering, spatial processing, equalization, virtual and/or dynamic bass enhancement, echo cancellation, automatic gain control, reverb, and tremolo. It is noted that an APO running on the CPU 308 may also be able to apply such audio effects.

The peripheral audio processing circuitry 304 is configured to output an output audio signal SO to the transducer 306 to be played back to the user, the output audio signal SO having optionally been subject to one or more audio effects applied by the ASP 316. It will be appreciated that in some situations the ASP 316 may be bypassed. In which case, no audio effects are applied to the output signal SO by the ASP 316.

As noted above, the system 300 comprises a controller 318 which is configured to dynamically adjust the audio effect or set of effects applied to the received audio signal. In the example shown in FIG. 3, the controller 318 is shown as separate from both the main circuitry 302 and the peripheral audio processing circuitry 304. It will be appreciated, however, that the controller 318 may be implemented in software by the main circuitry 302, or in hardware or software by the peripheral audio processing circuitry 304. For example, the controller 318 may be integrated into the peripheral audio processing circuitry 304. In another example, as shown in FIG. 3, the controller 318 may be provided as a separate hardware module.

Dynamic adjustment may comprise changing the number and order of effects being applied by the ASP 316. The processing to be applied to each audio signal in hardware may be configured based on one or more parameters of the respective audio signals. For example, processing may be based on the application which generated the audio signal or component thereof. For example, voice over internet protocol (VOIP) software such as Teams (RTM) or Zoom (RTM) may be run in raw (unprocessed) audio mode, the hardware configured to apply a baseline set of audio effects (described in more detail below). In another example, a media player may be configured to run a default or offload mode. In which case, more advanced hardware audio effects may be applied to condition resultant audio signals. In another example, if multiple applications are running concurrently, one or more apps may be prioritised for hardware audio processing. For example, VOIP apps may be prioritized to ensure clarity of communication to the detriment of media being played concurrently with an audio or video call. In another example, processing to be applied to each audio signal may be configured based on an acoustic configuration of device incorporating the system 300. Acoustic configurations may include but are note limited to: a type of an the device, one or more characteristics of the device, a characteristic of ambient sound in a vicinity of the device, a distance or a position of a user relative to the device for outputting the one or more processed audio signals, an orientation of the device (e.g. positional or rotational variance), an orientation of a display of the device, a number of transducers in the device, one or more audio characteristics of transducers of the device, and/or a contortion of the device (e.g. contortion of the screen relative to the body of a laptop of tablet computer).

To coordinate application of audio effects by the main and peripheral circuitry 302, 304, the controller 318 may have knowledge, directly or indirectly, of one or more characteristics of the software processed audio signal SA being output from the main circuitry 302 and/or the audio effects having been applied to that software processed audio signal SA. For example, the software processed audio signal SA or another output from the main circuitry 302 may comprise header information detailing the audio effects that have been applied to the software processed audio signal SA, or the audio effects to be applied to the software processed audio signal SA by the ASP 316. In another example, one or more data flags may be embedded into a data stream comprising the audio signal SA. In another example, the controller 318 may communicate with the main circuitry 302 and/or the peripheral audio processing circuitry 304 via a separate communications channel or bus. In another example, the CPU 308 may be configured to write to the memory 310 or another memory audio effects that are being applied by the main circuitry 302. In which case, the controller 318 may be in configured to access such information in memory to determine the audio effects that have been applied in software by the main circuitry 302. In yet a further example, the controller 318 may be configured to analyse the software processed audio signal SA to determine what audio effects (or a level of audio processing) that have been applied to obtain the software processed audio signal SA.

Based on the information described above pertaining to audio effects which have been applied to or which are required to be applied to the software processed audio signal SA, the controller 318 may control the ASP 316 to apply a set of audio effects to the audio signal.

In addition to retrieving information pertaining to audio effects applied to the software processed audio signal SA by the main circuitry 302, the controller 318 may be configured to indicate to the main circuitry 302 hardware audio effects that have been applied by the ASP 316. For example, the controller may be configured to write configuration data to the memory 310 of the main circuitry 302. Such configuration data may indicate audio effects which have been applied to the software processed audio signal SA. Configuration data may be provided in a device configuration table, for example provided as part of a system basic input/output system (BIOS) table.

As noted above, conventionally, APOs are designed so as to ensure baseline set of audio effects are applied to audio signals output from systems such as PCs, to maintain a threshold level of quality of those audio signals. Thus, to improve resilience of the system 300 to the removal or disruption of any APO running on the CPU 308, the controller 318 may be configured to control the ASP 316 to continuously apply a baseline set of audio effects. Such a baseline set of audio effects may be configured to maintain a quality of the output audio signal SO provided to the transducer 306 irrespective of the presence or absence of an APO running on the CPU 308. Where one or more of these baseline audio effects are not implemented by the main circuitry 302 (e.g. by an APO running on the CPU 308), the controller 318 may be configured to control the ASP to apply such effects, thereby ensuring that such baseline audio effects are always applied to any audio signal output to the transducer 306. Examples of baseline audio effects include but are not limited to baseline speaker protection, rattle distortion reduction, distorting limiting, and crossover filtering.

In addition, or as an alternative to maintaining baseline audio effects, the controller 318 may be configured to selectively enable and/or disable one or more additional effects, such as those described above. Example additional effects include but are not limited to spatial processing, equalisation, virtual bass enhancement, dynamic bass enhancement, and the like.

As with the arrangement shown in FIG. 1, the main circuitry 302 may be configurable to output multiple audio output streams. For example, the main circuitry 302 may be configured to output both RAW and default audio data streams, RAW being substantially unprocessed, and default having some level of baseline software processing being implemented. Likewise, the peripheral audio processing circuitry 304 may be configurable to receiving multiple audio input streams. The peripheral audio processing circuitry 304 may be configured to apply audio effects to each input audio stream independently. For example, if first and second input audio signals are received by the peripheral audio processing circuitry 304, the ASP 316 may be configurable (e.g. by the controller 318) to apply a first set of audio effects to the first input audio signal, and a second set of audio effects (which may be different or the same) to the second audio signal. Thus, the controller 318 may be configured to dynamically adjust audio effects applied by the ASP 316 to each audio signal received at the peripheral audio processing circuitry 304. Such control may be in the manner described above with respect to the software processed audio signal SA.

Where multiple input audio streams are provided to the peripheral audio processing circuitry 304, the ASP 316 may be configured to mix multiple audio signals (either before or after applying respective audio effects).

Thus, the system 300 provides a novel system architecture which ensures quality of audio processing to be maintained regardless of software level interference by third parties.

FIG. 4 is a flow diagram illustrating an example audio processing flow for the system 300 of FIG. 3. In this example, one or more applications 402 generate first and second audio streams A1, A2. For example, the first audio stream A1 may be from a voice over internet protocol (VOIP) session, and the second audio stream A2 may be generated from a media stream (music or video). It will, however, be appreciated that any number of audio streams may be generated at the application level, each from any type of application.

The first and second audio streams A1, A2 are processed by the CPU 308, for example running an APO, as shown in FIG. 3. Specifically, the CPU 308 applies mode audio effects (MFX) to the first audio stream A1, whilst the second audio stream A2 is passed to the peripheral audio processing circuitry 304 via an audio driver 404 without any audio effects having been applied.

The peripheral audio processing circuitry 304 receives the first processed audio stream A1 and the second (unprocessed) audio stream A2. The controller 318, with knowledge of the audio effects applied by the CPU 308 at the software level, controls the ASP 316 to apply different sets of audio effects to each audio stream A1, A2. Specifically, since mode effects were not applied to the second audio stream A2 at the software level, the controller 318 controls the ASP 316 to apply mode effects to the second audio stream A2. The controller 318 the controls the ASP 316 to apply end effects to the mixed first and second audio streams A1, A2 to obtain the output signal SO provided to the transducer 306.

It will be appreciated that the processing flow 400 shown in FIG. 4 is an example only, and any conceivable combination of audio effects may be applied by each of the main and peripheral audio processing circuitry 302, 304. In any case, the controller 318 ensures that handoff between the main and peripheral audio processing circuitry 302, 304 is managed to ensure smooth operation of the split software/hardware audio processing system 300.

In the system 300 shown in FIG. 3, the ASP 316 is integrated with the peripheral audio processing circuitry 304. However, embodiments are not limited to such an arrangement.

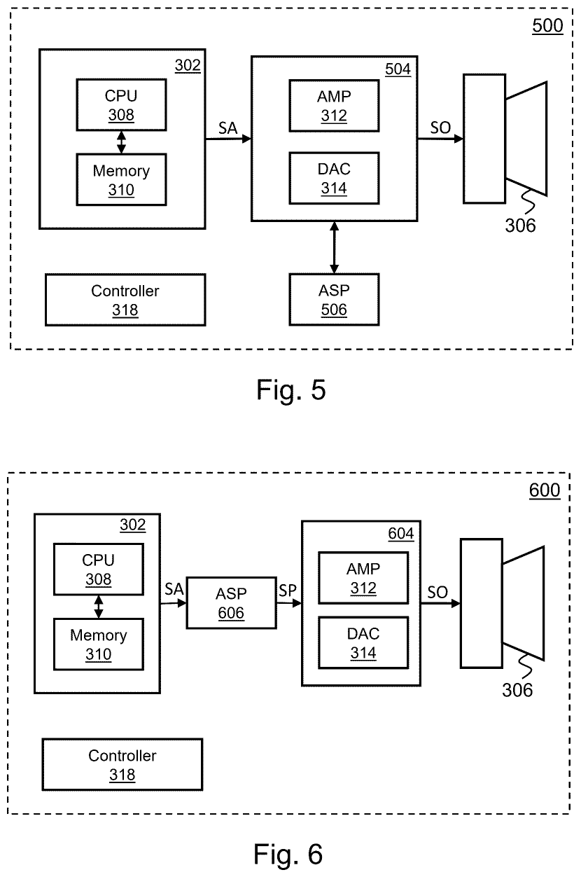

FIG. 5 is a schematic diagram of a system 500 which is a variation of the system 300 shown in FIG. 3, like parts given like numbers. The peripheral audio processing circuitry 304 is replaced with peripheral audio processing circuitry 504 which omits the ASP 316. Instead, an ASP 506 is provided in a sidecar arrangement in communication with the peripheral audio processing circuitry 504. In such an arrangement, the peripheral audio processing circuitry 504 may output audio signals to the ASP 506 for audio effects to be applied, the ASP 506 then sending processed audio signals back to the peripheral audio processing circuitry 504 for output to the transducer 306 or further processing.

FIG. 6 is a schematic diagram of a system 600 which is another variation of the system 300 shown in FIG. 5, like parts given like numbering. The peripheral audio processing circuitry 304 is replaced with peripheral audio processing circuitry 604 which omits the ASP 316. Instead, an ASP 606 is provided in series between the main circuitry 302 and the peripheral audio processing circuitry 604. In such an arrangement, the ASP 606 is configured to apply audio effects to the audio signal SA output from the main circuitry 302 and a processed audio signal SP is output to the peripheral audio processing circuitry 604 for amplification and/or conversion to the analog domain.

In each of the systems 500, 600 shown in FIGS. 5 and 6, the controller 318 is configured to control the circuitry in a manner similar to that described above with reference to the system 300 of FIG. 3.

As used herein, when two or more elements are referred to as “coupled” to one another, such term indicates that such two or more elements are in electronic communication or mechanical communication, as applicable, whether connected indirectly or directly, with or without intervening elements.

This disclosure encompasses all changes, substitutions, variations, alterations, and modifications to the example embodiments herein that a person having ordinary skill in the art would comprehend. Similarly, where appropriate, the appended claims encompass all changes, substitutions, variations, alterations, and modifications to the example embodiments herein that a person having ordinary skill in the art would comprehend. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative. Accordingly, modifications, additions, or omissions may be made to the systems, apparatuses, and methods described herein without departing from the scope of the disclosure. For example, the components of the systems and apparatuses may be integrated or separated. Moreover, the operations of the systems and apparatuses disclosed herein may be performed by more, fewer, or other components and the methods described may include more, fewer, or other steps. Additionally, steps may be performed in any suitable order. As used in this document, “each” refers to each member of a set or each member of a subset of a set.

Although exemplary embodiments are illustrated in the figures and described below, the principles of the present disclosure may be implemented using any number of techniques, whether currently known or not. The present disclosure should in no way be limited to the exemplary implementations and techniques illustrated in the drawings and described above.

Unless otherwise specifically noted, articles depicted in the drawings are not necessarily drawn to scale.

All examples and conditional language recited herein are intended for pedagogical objects to aid the reader in understanding the disclosure and the concepts contributed by the inventor to furthering the art and are construed as being without limitation to such specifically recited examples and conditions. Although embodiments of the present disclosure have been described in detail, it should be understood that various changes, substitutions, and alterations could be made hereto without departing from the spirit and scope of the disclosure.

Although specific advantages have been enumerated above, various embodiments may include some, none, or all of the enumerated advantages.

Additionally, other technical advantages may become readily apparent to one of ordinary skill in the art after review of the foregoing figures and description.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single feature or other unit may fulfil the functions of several units recited in the claims. Any reference numerals or labels in the claims shall not be construed so as to limit their scope.

1. A system, comprising:
main circuitry, comprising:
a central processor;
memory comprising software instructions which when executed by the central processor cause the central processor to:
selectively apply one or more software audio effects to an audio signal to generate a first software processed audio signal; and
output the first software processed audio signal;
audio processing circuitry, comprising:
an audio processor configured to:
receive the first software processed audio signal;
apply first hardware audio effects to the first software audio signal to generate a first hardware processed audio signal; and
output an output audio signal derived from the first hardware processed audio signal; and
a controller configured to dynamically adjust the first hardware audio effects applied to the first software processed audio signal in dependence on a characteristic of the first software processed audio signal.

2. The system of claim 1, wherein the controller is implemented in software by the main circuitry.

3. The system of claim 1, wherein the controller is implemented in hardware.

4. The system of claim 3, wherein the controller is integrated into the audio processing sub-system.

5. The system of claim 1, wherein the controller is configured to dynamically adjust the first hardware effects based on one or more of:
a. header information in a data stream comprising the first software processed audio signal; and
b. one or more data flags embedded into the data stream;
c. one or more data flags obtained from the main circuitry.

6. The system of claim 1, wherein the controller is configured to dynamically adjust the first hardware effects based on analysis of the first software processed audio signal.

7. The system of claim 6, wherein analysis of the first software processed audio signal comprises determining a level of processing performed on the audio signal to obtain the first software processed audio signal.

8. The system of claim 1, wherein the controller is configured to dynamically adjust the first hardware audio effects based on a command from the central processor or based on a configuration set by the central processor.

9. The system of claim 1, wherein the first hardware audio effects comprise one or more of:
a. baseline speaker protection;
b. rattle distortion reduction;
c. distortion limiting;
d. crossover filtering;
e. spatial processing;
f. equalization;
g. virtual and/or dynamic bass enhancement.

10. The system of claim 1, wherein the controller is configured to control the audio processor to continuously apply baseline hardware audio effects to the first software processed audio signal to maintain a quality metric of the first hardware processed audio signal above a predetermined quality threshold.

11. The system of claim 10, wherein the baseline set of hardware audio effects comprises one or more of:
a. baseline speaker protection;
b. rattle distortion reduction;
c. distortion limiting;
d. crossover filtering.

12. The system of claim 10, wherein the first hardware audio effects comprise one or more of:
a. spatial processing;
b. equalization;
c. virtual and/or dynamic bass enhancement.

13. The system of claim 1, wherein the main circuitry is configured to output the audio signal, and wherein the audio processor is configured to:
receive the audio signal via a separate input path to the first software processed audio signal; and
apply second hardware audio effects to the audio signal to obtain a second hardware processed audio signal.

14. The system of claim 13, wherein the controller is configured to dynamically adjust the second hardware audio effects applied to the audio signal.

15. The system of claim 13, wherein the audio processor is configured to:
mix the first and second hardware processed audio signals to obtain the output audio signal.

16. The system of claim 1, further comprising:
a communications channel between the main circuitry and the audio processing circuitry.

17. The system of claim 1, wherein the audio processor and/or the controller are configured to write configuration data to the memory of the main circuitry, the configuration data indicating the first hardware audio effects applied to the first software processed audio signal.

18. The system of claim 1, further comprising an audio transducer configured to receive the output audio signal.

19. The system of claim 1, wherein the audio processing circuitry comprises an amplifier configured to amplify the first hardware processed audio signal to obtain the output audio signal.

20. The system of claim 1, wherein the first hardware processed audio signal is a digital signal, and wherein the audio processing circuitry comprises a digital-to-analog converter (DAC) for converting the first hardware processed audio signal to the analog domain.

21. The system of claim 1, wherein the audio processing circuitry comprises an audio CODEC configured to generate the output audio signal.

22. The system of claim 1, wherein the main circuitry is integrated into a first integrated circuit (IC), and wherein the audio processing circuitry is integrated into a second IC separate from the first IC.

23. The system of claim 22, wherein the controller is integrated into the second IC.

24. The system of claim 22, wherein the controller is integrated into a third IC separate from the first and second ICs.

25. An audio processor integrated circuit, comprising:
audio processing circuitry, comprising:
an audio processor configured to:
receive a first software processed audio signal;
apply first hardware audio effects to the first software audio signal to generate a first hardware processed audio signal; and
output an output audio signal derived from the first hardware processed audio signal; and
a controller configured to dynamically adjust the first hardware audio effects applied to the first software processed audio signal in dependence on a characteristic of the first software processed audio signal.

26. A system, comprising:
main circuitry, comprising:
a central processor;
memory comprising software instructions which when executed by the central processor cause the central processor to:
selectively apply one or more software audio effects to an audio signal to generate a first software processed audio signal; and
output the audio signal and the first software processed audio signal;
audio processing circuitry, comprising:
an audio processor configured to:
receive the audio signal and the first software processed audio signal;
apply first hardware audio effects to the audio signal to generate a first hardware processed audio signal;
apply second hardware audio effects to the first software audio signal to generate a second hardware processed audio signal;
mix the first and second hardware processed audio signals to generate a mixed hardware processed signal; and
output an output audio signal derived from the mixed hardware processed audio signal.

27. The system of claim 26, wherein the main circuitry comprises a class driver and a streaming driver stored in the memory which, when executed by the central processor, cause the processor to output the audio signal and the first software processed audio signal to first and second data ports of the main circuitry.

28. An audio processor integrated circuit, comprising audio processing circuitry configured to:
receive an audio signal and a first software processed audio signal, one or more software audio effects having been applied to the audio signal to generate the first software processed audio signal;
apply first hardware audio effects to the audio signal to generate a first hardware processed audio signal;
apply second hardware audio effects to the first software audio signal to generate a second hardware processed audio signal;
mix the first and second hardware processed audio signals to generate a mixed hardware processed signal; and
output an output audio signal derived from the mixed hardware processed audio signal.

29. An electronic device, comprising the system of claim 1.

30. The electronic device of claim 29, wherein the electronic device comprises one of a wearable device, an analyte monitoring device, an analyte sensing device, a battery, a battery monitoring device, a mobile computing device, a laptop computer, a tablet computer, a games console, a remote control device, a home automation controller or a domestic appliance, a toy, a robot, an audio player, a video player, or a mobile telephone, and a smartphone.
